(19) United States
(12) Patent Application Publication
(10) Pub. No.: US 2024/0155923 A1
(43) Pub. Date: May 9, 2024

(54) DISPLAY DEVICE AND METHOD FOR MANUFACTURING THE SAME

(71) Applicant: Samsung Display Co., LTD., Yongin-si (KR)

(72) Inventors: MIHWA LEE, Yongin-si (KR); HYEOJI KANG, Yongin-si (KR); OHJEONG KWON, Yongin-si (KR); TAEHO KIM, Yongin-si (KR); HONGYEON LEE, Yongin-si (KR); SUNGGYU JANG, Yongin-si (KR); SEUNGYEON JEONG, Yongin-si (KR)

(73) Assignee: Samsung Display Co., LTD., Yongin-si (KR)

(21) Appl. No.: 18/354,059

(22) Filed: Jul. 18, 2023

(30) Foreign Application Priority Data
Nov. 7, 2022 (KR) 10-2022-0147047

(51) Int. Cl. H10K 59/80; H10K 59/12; H10K 59/40

(52) U.S. Cl. CPC H10K 59/8791; H10K 59/1201; H10K 59/40

(57) ABSTRACT

A display device includes a light emitting area and a non-light emitting area, a light emitting element disposed in the light emitting area on a substrate and including a pixel electrode, a light emitting layer, and an upper electrode, the pixel electrode, light emitting layer, and upper electrode being sequentially disposed, a light blocking layer disposed on the light emitting element in the non-light emitting area, and a reflection control layer disposed on the light emitting element, covering the light blocking layer, and including a recess depressed concavely from an upper surface in the light emitting area.

### CROSS-REFERENCE TO RELATED APPLICATION

This application claims priority to and benefits of Korean Patent Application No. 10-2022-0147047 under 35 U.S.C. § 119, filed on Nov. 7, 2022 in the Korean Intellectual Property Office (KIPO), the entire contents of which are hereby incorporated by reference.

### BACKGROUND

### 1. Technical Field

Embodiments relate generally to display device. More specifically, embodiments relate to a display device that provides visual information.

### 2. Description of the Related Art

With the development of information technology, the importance of a display device, which is a connection medium between a user and information, has been highlighted. For example, the use of display devices such as liquid crystal display device, organic light emitting display device, plasma display device, or the like is increasing.

Since the display device includes lines, electrodes, and the like including metal, external light incident on the display device may be reflected from the lines and electrodes. In order to prevent reflection by external light, the display device generally includes a polarizer. However, while the polarizer may prevent reflection by external light, light efficiency of the display device may be reduced due to the polarizer.

### SUMMARY

Embodiments provide an improved display device with reduced defect.

Embodiments provide a method of manufacturing the display device.

The technical objectives to be achieved by the disclosure are not limited to those described herein, and other technical objectives that are not mentioned herein would be clearly understood by a person skilled in the art from the description of the disclosure.

A display device according to embodiments of the disclosure may include a light emitting area and a non-light emitting area, a light emitting element disposed in the light emitting area on a substrate and including a pixel electrode, a light emitting layer, and an upper electrode, the pixel electrode, light emitting layer, and upper electrode being sequentially disposed, a light blocking layer disposed on the light emitting element in the non-light emitting area, and a reflection control layer disposed on the light emitting element, covering the light blocking layer, and including a recess depressed concavely from an upper surface in the light emitting area.

In an embodiment, the display device may further include an adhesive layer disposed on the reflection control layer. A refractive index of the adhesive layer may be greater than a refractive index of the reflection control layer.

In an embodiment, a difference between the refractive index of the adhesive layer and the refractive index of the reflection control layer may be about 0.05 or more.

In an embodiment, the adhesive layer directly may contact the reflection control layer.

In an embodiment, the display device may further include a filling layer disposed between the light emitting element and the reflection control layer. A refractive index of the filling layer may be greater than a refractive index of the reflection control layer.

In an embodiment, the filling layer directly may contact the reflection control layer.

In an embodiment, a difference between the refractive index of the filling layer and the refractive index of the reflection control layer may be about 0.05 or more.

In an embodiment, the display device may further include a light absorbing layer disposed on the upper electrode and including an inorganic material.

In an embodiment, the light absorbing layer may be disposed only in the light emitting area.

In an embodiment, the light absorbing layer may be entirely disposed in the light emitting area and the non-light emitting area.

In an embodiment, the light absorbing layer may include at least one selected from a group consisting of a metal, a silicon compound, and a metal oxide.

In an embodiment, the reflection control layer may include an inorganic material or an organic material.

In an embodiment, the reflection control layer may further include at least one selected from a group consisting of solvent, dye, pigment, and surfactant.

In an embodiment, the organic material may include photoresist.

In an embodiment, the display device may further include a touch sensing layer disposed between the light emitting element and the light blocking layer, and including a first touch electrode and a second touch electrode electrically connected to the first touch electrode.

A method of manufacturing a display device according to embodiments of the disclosure, the method may include forming a light emitting element including a pixel electrode, a light emitting layer, and an upper electrode sequentially formed in a light emitting area of the display device on a substrate, forming a light blocking layer in a non-light emitting area of the display device on the light emitting element, forming a preliminary reflection control layer covering the light blocking layer on the light emitting element, and forming a reflection control layer including a recess concavely depressed from an upper surface in the light emitting area by removing a portion of the preliminary reflection control layer in the light emitting area.

In an embodiment, the forming the reflection control layer may be performed by using a halftone mask or a slit mask.

In an embodiment, the method may further include forming an adhesive layer on the reflection control layer. A refractive index of the adhesive layer may be greater than a refractive index of the reflection control layer.

In an embodiment, a difference between the refractive index of the adhesive layer and the refractive index of the reflection control layer may be about 0.05 or more.

In an embodiment, the adhesive layer directly may contact the reflection control layer.

In an embodiment, the method may further include forming a light absorbing layer including an inorganic material on the upper electrode after the forming of the light emitting element.

In an embodiment, the reflection control layer may include an inorganic material or an organic material.

In an embodiment, the reflection control layer may further include at least one selected from a group consisting of solvent, dye, pigment, and surfactant.

A display device according to an embodiment of the disclosure may include a light emitting area and a non-light emitting area, a light emitting element disposed in the light emitting area on a substrate, a light blocking layer disposed on the light emitting element in the non-light emitting area, a reflection control layer disposed on the light emitting element and defining a recess concavely depressed from an upper surface in the light emitting area, and a high refractive index layer (e.g., an adhesive layer or a filling layer) directly contacting the reflection control layer. A refractive index of the high refractive index layer may be greater than a refractive index of the reflection control layer. Accordingly, light efficiency of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a schematic plan view illustrating a display device according to an embodiment of the disclosure.

FIG. 2 is a schematic cross-sectional view taken along line I-I′ of FIG. 1.

FIGS. 3, 4, 5, 6, 7, 8, and 9 are schematic cross-sectional views for explaining a method of manufacturing the display device of FIG. 2.

FIG. 10 is a schematic cross-sectional view illustrating a display device according to another embodiment of the present disclosure.

FIG. 11 is a schematic plan view illustrating a display device according to another embodiment of the disclosure.

FIG. 12 is a schematic cross-sectional view schematically illustrating the display device of FIG. 11.

FIG. 13 is a schematic cross-sectional view taken along line II-Ir of FIG. 11.

FIGS. 14, 15, 16, 17, and 18 are schematic cross-sectional views for explaining a method of manufacturing the display device of FIG. 13.

FIG. 19 is a schematic block diagram illustrating an electronic device including the display device of FIG. 1.

FIG. 20 is a schematic diagram illustrating an example in which the electronic device of FIG. 19 is implemented as a television.

FIG. 21 is a schematic diagram illustrating an example in which the electronic device of FIG. 19 is implemented as a smartphone.

### DETAILED DESCRIPTION OF THE EMBODIMENTS

Hereinafter, a display device according to embodiments of the disclosure will be explained in detail with reference to the accompanying drawings. The same reference numerals and/or reference characters are used for the same components in the drawings, and redundant descriptions of the same components will be omitted.

When an element is referred to as being “on,” “connected to,” or “coupled to” another element, it may be directly on, connected to, or coupled to the other element or intervening elements or layers may be present. When, however, an element is referred to as being “directly on,” “directly connected to,” or “directly coupled to” another element, there are no intervening elements or layers present. To this end, the term “connected” may refer to physical, electrical, and/or fluid connection, with or without intervening elements.

The term “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

In the disclosure, the singular forms (such as “a” and “an”) are intended to include the plural meanings as well, unless the context clearly indicates otherwise.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

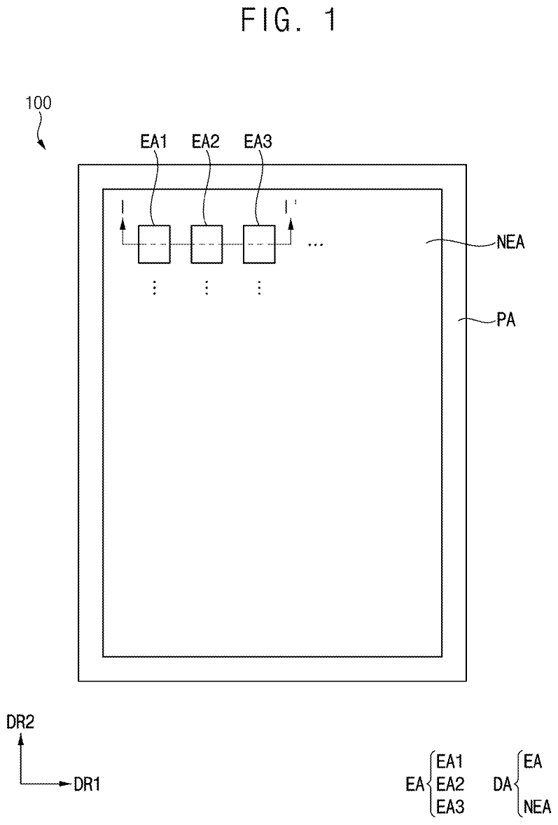

FIG. 1 is a schematic plan view illustrating a display device according to an embodiment of the disclosure.

Referring to FIG. 1, a display device 100 according to an embodiment may include a display area DA and a peripheral area PA. The display area DA may be an area that displays an image. The peripheral area PA may be an area that does not display an image. The peripheral area PA may be located adjacent to or around the display area DA. For example, the peripheral area PA may entirely surround the display area DA.

The display area DA may include light emitting areas EA and a non-light emitting area NEA. Each of the light emitting areas EA may include a first light emitting area EA1, a second light emitting area EA2, and a third light emitting area EA3.

Each of the first light emitting area EA1, the second light emitting area EA2, and the third light emitting area EA3 may refer to an area in which light emitted from a light emitting element is emitted to the outside of the display device 100. For example, the first light emitting area EA1 may emit first light, the second light emitting area EA2 may emit second light, and the third light emitting area EA3 may emit third light. In an embodiment, the first light may be red light, the second light may be green light, and the third light may be blue light. However, the disclosure is not limited thereto. For example, the light emitting areas EA may emit, separately or in combination, yellow, cyan, and magenta lights.

The light emitting areas EA may emit light of four or more colors. For example, the light emitting areas EA may emit, separately or in combination, at least one of yellow, cyan, and magenta lights in addition to red, green, and blue lights. The light emitting areas EA may emit, separately or in combination, white light.

In a plan view, each of the first light emitting area EA1, the second light emitting area EA2, and the third light emitting area EA3 may be repeatedly arranged in a row direction and a column direction. In the plan view, the first light emitting area EA1, the second light emitting area EA2, and the third light emitting area EA3 may be repeatedly arranged in a first direction DR1 and a second direction DR2 crossing (or intersecting) the first direction DR1.

Each of the first light emitting area EA1, the second light emitting area EA2, and the third light emitting area EA3 may have a triangular planar shape, a quadrangular planar shape, a circular planar shape, a track-shaped planar shape, an elliptical planar shape, or the like. In an embodiment, each of the first light emitting area EA1, the second light emitting area EA2, and the third light emitting area EA3 may have a rectangular planar shape. However, the disclosure is not limited thereto, and each of the first light emitting area EA1, the second light emitting area EA2, and the third light emitting area EA3 may have a different planar shape.

The non-light emitting area NEA may be located between the first light emitting area EA1, the second light emitting area EA2, and the third light emitting area EA3. For example, in the plan view, the non-light emitting area NEA may surround the first light emitting area EA1, the second light emitting area EA2, and the third light emitting area EA3. The-non-light emitting area NEA may not emit light.

In this specification, a plane may be defined as the first direction DR1 and the second direction DR2. For example, the first direction DR1 may be perpendicular to the second direction DR2.

The display device 100 of the disclosure may at least one of display devices including, e.g., an organic light emitting display device (OLED), a liquid crystal display device (LCD), a field emission display device (FED), a plasma display device (PDP), an electrophoretic display device (EPD), and an inorganic light emitting display device (ILED).

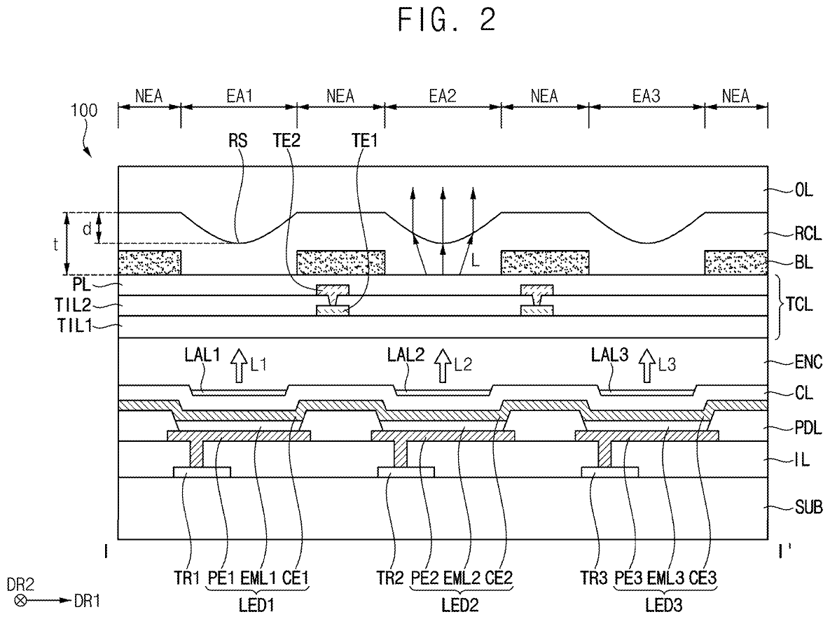

FIG. 2 is a schematic cross-sectional view taken along line I-I′ of FIG. 1.

Referring to FIG. 2, the display device 100 according to an embodiment may include a substrate SUB, first, second, and third transistors TR1, TR2, and TR3, an insulating structure IL, a pixel defining layer PDL, first, second, and third light emitting elements LED1, LED2, and LED3, a capping layer CL, first, second, and third light absorbing layers LAL1, LAL2, and LAL3, an encapsulation layer ENC, a touch sensing layer TCL, a light blocking layer BL, a reflection control layer RCL, and an adhesive layer OL.

The first light emitting element LED1 may include a first pixel electrode PE1, a first light emitting layer EML1, and a first common electrode CE1. The second light emitting element LED2 may include a second pixel electrode PE2, a second light emitting layer EML2, and the second common electrode CE2. The third light emitting element LED3 may include a third pixel electrode PE3, a third light emitting layer EML3, and a third common electrode CE3.

As described above, the display device 100 may include first, second, and third light emitting areas EA1, EA2, and EA3 and a non-light emitting area NEA. As the display device 100 may include the first, second, and third light emitting areas EA1, EA2, and EA3 and the non-light emitting area NEA, components (or elements, e.g., the substrate (SUB)) included in the display device 100 may also include the first, second, and third light emitting areas EA1, EA2, and EA3 and the non-light emitting area NEA.

The substrate SUB may include a transparent material and/or an opaque material. The substrate SUB may be made of (or may include), e.g., a transparent resin substrate. Examples of the transparent resin substrate may include polyimide substrates and the like. The polyimide substrate may include a first organic layer, a first barrier layer, and a second organic layer. As another example, the substrate SUB may include, e.g., a quartz substrate, a synthetic quartz substrate, a calcium fluoride substrate, an F-doped quartz substrate, a soda-lime glass substrate, a non-alkali glass substrate, and the like. These may be used alone or in combination with each other.

The first, second, and third transistors TR1, TR2, and TR3 may be disposed on the substrate SUB. For example, each of the first, second, and third transistors TR1, TR2, and TR3 may include at least one of amorphous silicon, polycrystalline silicon, and a metal oxide semiconductor. In an embodiment, each of the first, second, and third transistors TR1, TR2, and TR3 may be a thin-film transistor.

The metal oxide semiconductor may include, e.g., at least one of a two-component compound (ABₓ), a ternary compound (ABₓC_{y}), a four-component compound (ABₓC_{y}D_{z}), and the like containing indium (In), zinc (Zn), gallium (Ga), tin (Sn), titanium (Ti), aluminum (Al), hafnium (Hf), zirconium (Zr), magnesium (Mg), and the like. For example, the metal oxide semiconductor may include at least one of zinc oxide (ZnOₓ), gallium oxide (GaOₓ), tin oxide (SnOₓ), indium oxide (InOₓ), indium gallium oxide (IGO), indium zinc oxide (IZO), indium tin oxide. (ITO), indium zinc tin oxide (IZTO), indium gallium zinc oxide (IGZO), and the like. These may be used alone or in combination with each other.

The insulating structure IL may be disposed on the substrate SUB. The insulating structure IL may cover (or overlap) the first, second, and third transistors TR1, TR2, and TR3. The insulating structure IL may include at least one of an inorganic insulating layer and an organic insulating layer. For example, the inorganic insulating layer may include at least one of silicon oxide (SiOₓ), silicon nitride (SiNₓ), silicon carbide (SiCₓ), silicon oxynitride (SiOₓN_{y}), silicon oxycarbide (SiOₓC_{y}), and the like. The organic insulating layer may include at least one of photoresist, polyacryl-based resin, polyimide-based resin, polyamide-based resin, siloxane-based resin, acrylic-based resin, epoxy-based resin, and the like. Each of these may be used alone or in combination with each other.

The first, second, and third pixel electrodes PE1, PE2, and PE3 may be disposed on the insulating structure IL. The first pixel electrode PE1 may overlap the first light emitting area EA1, the second pixel electrode PE2 may overlap the second light emitting area EA2, and the third pixel electrode PE3 may overlap the third light emitting area EA3, in a view or direction (e.g., in a plan view). The first pixel electrode PE1 may be electrically connected to the first transistor TR1 through a first contact hole passing through the insulating structure IL, the second pixel electrode PE2 may be electrically connected to the second transistor TR2 through a second contact hole passing through the insulating structure IL, and the third pixel electrode PE3 may be electrically connected to the third transistor TR3 through a third contact hole passing through the insulating structure IL. For example, each of the first, second, and third pixel electrodes PE1, PE2, and PE3 may include at least one of a metal, an alloy, a metal nitride, a conductive metal oxide, a transparent conductive material, and the like. These may be used alone or in combination with each other. Each of the first, second, and third pixel electrodes PE1, PE2, and PE3 may function as an anode.

The pixel defining layer PDL may be disposed on the insulating structure IL and the first, second, and third pixel electrodes PE1, PE2, and PE3. The pixel defining layer PDL may overlap the non-light emitting area NEA. The pixel defining layer PDL may cover sides (e.g., both sides) of each of the first, second, and third pixel electrodes PE1, PE2, and PE3 and may expose at least a portion of an upper surface of each of the first, second, and third pixel electrodes PE1, PE2, and PE3. The pixel defining layer PDL may include an organic material and/or an inorganic material. In an embodiment, the pixel defining layer PDL may include an organic material. For example, the pixel defining layer PDL may include at least one of photoresist, polyacrylic resin, polyimide resin, polyamide resin, siloxane resin, acrylic resin, epoxy resin, and the like. These may be used alone or in combination with each other.

The first light emitting layer EML1 may be disposed on the first pixel electrode PE1, the second light emitting layer EML2 may be disposed on the second pixel electrode PE2, and the third light emitting layer EML3 may be disposed on the third pixel electrode PE3. For example, each of the first, second, and third light emitting layers EML1, EML2, and EML3 may include an organic material emitting light of a color (e.g., a predetermined or selectable color). The first light emitting layer EML1 may include an organic material that emits a first-color light L1, the second light emitting layer EML2 may include an organic material that emits a second-color light L2, and the third light emitting layer EML3 may include an organic material that emits a third-color light L3. For example, the first color may be red, the second color may be green, and the third color may be blue. However, the disclosure is not limited thereto.

The first common electrode CE1 may be disposed on the first light emitting layer EML1 and the pixel defining layer PDL, the second common electrode CE2 may be disposed on the second light emitting layer EML2 and the pixel defining layer PDL, and the third common electrode CE3 may be disposed on the third light emitting layer EML3 and the pixel defining layer PDL. The first, second, and third common electrodes CE1, CE2, and CE3 may be integrally formed (or integral with each other). For example, each of the first, second, and third common electrodes CE1, CE2, and CE3 may include a metal, an alloy, a metal nitride, a conductive metal oxide, a transparent conductive material, and the like. These may be used alone or in combination with each other. The first, second, and third common electrodes CE1, CE2, and CE3 may operate as a cathode.

Accordingly, the first light emitting element LED1 including the first pixel electrode PE1, the first light emitting layer EML1, and the first common electrode CE1 may be disposed in the first light emitting area EA1 on the substrate SUB. The second light emitting element LED2 including the second pixel electrode PE2, the second light emitting layer EML2, and the second common electrode CE2 may be disposed in the second light emitting area EA2 on the substrate SUB. The third light emitting element LED3 including the third pixel electrode PE3, the third light emitting layer EML3, and the third common electrode CE3 may be disposed in the third light emitting area EA3 on the substrate SUB.

The first light emitting element LED1 may be electrically connected to the first transistor TR1, the second light emitting element LED2 may be electrically connected to the second transistor TR2, and the third light emitting element LED3 may be electrically connected to the transistor TR3.

The capping layer CL may be disposed on the first, second, and third common electrodes (or upper electrodes) CE1, CE2, and CE3. The capping layer CL may be entirely disposed on the first, second, and third common electrodes CE1, CE2, and CE3. The capping layer CL may serve to protect the first, second, and third common electrodes CE1, CE2, and CE3. For example, the capping layer CL may include an organic material and/or an inorganic material.

The first, second, and third light absorbing layers LAL1, LAL2, and LAL3 may be disposed on the capping layer CL. The first light absorbing layer LAL1 may overlap the first light emitting area EA1, the second light absorbing layer LAL2 may overlap the second light emitting area EA2, and the third light absorbing layer LAL3 may overlap the third light emitting area EA3. The first, second, and third light absorbing layers LAL1, LAL2, and LAL3 may absorb external light. Each of the first, second, and third light absorbing layers LAL1, LAL2, and LAL3 may include an inorganic material and/or organic material.

For example, each of the first, second, and third light absorbing layers LAL1, LAL2, and LAL3 may include an inorganic material such as a metal, a silicon compound, a metal oxide, and the like. Examples of the metal may include silver (Ag), aluminum (Al), magnesium (Mg), chromium (Cr), titanium (Ti), nickel (Ni), gold (Au), tantalum (Ta), copper (Cu), calcium (Ca), cobalt (Co), iron (Fe), molybdenum (Mo), tungsten (W), platinum (Pt), ytterbium (Yb), and the like. Examples of the silicon compound may include silicon oxide (SiO₂), silicon nitride (SiNₓ), and the like. Examples of the metal oxide may include titanium oxide (TiO₂), zirconium oxide (ZrO₂), tantalum oxide (Ta₂O₅), hafnium oxide (HfO₂), aluminum oxide (Al₂O₃), zinc oxide (ZnO), yttrium oxide (Y₂O₃), beryllium oxide (BeO), magnesium oxide (MgO), lead oxide (PbO₂), tungsten oxide (WO₃), and the like. Each of these may be used alone or in combination with each other. As another example, each of the first, second, and third light absorbing layers LAL1, LAL2, and LAL3 may include an inorganic material such as lithium fluoride (LiF), calcium fluoride (CaF₂), magnesium fluoride (MgF²), cadmium sulfide (CdS), and the like. These may be used alone or in combination with each other.

The encapsulation layer ENC may be disposed on the capping layer CL and the first, second, and third light absorbing layers LAL1, LAL2, and LAL3. The encapsulation layer ENC may prevent impurities, moisture, and the like from permeating through the first, second, and third light emitting elements LED1, LED2, and LED3 from the outside. The encapsulation layer ENC may include at least one of an inorganic encapsulation layer and an organic encapsulation layer. For example, the inorganic encapsulation layer may include at least one of silicon oxide, silicon nitride, silicon oxynitride, and the like, and the organic encapsulation layer may include at least one of a polymer cured material such as polyacrylate, and the like.

The touch sensing layer TCL may be disposed on the encapsulation layer ENC. The touch sensing layer TCL may function as an input unit of the display device 100. The touch sensing layer TCL may include at least one of a first touch insulating layer TILL a second touch insulating layer TIL2, a first touch electrode TE1, a second touch electrode TE2, and a protective layer PL.

The first touch insulating layer TIL1 may be disposed on the encapsulation layer ENC. The first touch insulating layer TIL1 may include an inorganic material and/or an organic material. For example, the first touch insulating layer TIL1 may include an inorganic material such as silicon oxide, silicon nitride, and the like. These may be used alone or in combination with each other.

The first touch electrode TE1 may be disposed on the first touch insulating layer TIL1. The first touch electrode TE1 may overlap the non-light emitting area NEA. For example, the first touch electrode TE1 may include at least one of a metal, an alloy, a metal nitride, a conductive metal oxide, a transparent conductive material, and the like. These may be used alone or in combination with each other.

The second touch insulating layer TIL2 may be disposed on the first touch insulating layer TIL1 and the first touch electrode TE1 The second touch insulating layer TIL2 may sufficiently cover the first touch electrode TE1 The second touch insulating layer TIL2 may include an inorganic material or an organic material. For example, the second touch insulating layer TIL2 may include an inorganic material such as silicon oxide, silicon nitride, and the like. These may be used alone or in combination with each other.

The second touch electrode TE2 may be disposed on the second touch insulating layer TIL2. The second touch electrode TE2 may overlap the non-light emitting area NEA. The second touch electrode TE2 may be electrically connected to the first touch electrode TE1 through a contact hole passing through the second touch insulating layer TIL2. For example, the second touch electrode TE2 may include at least one of carbon nano tube (CNT), transparent conductive oxide, indium tin oxide (ITO), indium gallium zinc oxide (IGZO), zinc oxide (ZnO), graphene, silver nanowire (AgNW), copper (Cu), chromium (Cr), and the like. These may be used alone or in combination with each other.

The first touch electrode TE1 and the second touch electrode TE2 may include a same material. As another example, the first touch electrode TE1 and the second touch electrode TE2 may include different materials.

The protective layer PL may be disposed on the second touch insulating layer TIL2 and the second touch electrode TE2. The protective layer PL may sufficiently cover the second touch electrode TE2. The protective layer PL may protect the first touch electrode TE1 and the second touch electrode TE2. The protective layer PL may include an inorganic material and/or an organic material. For example, the protective layer PL may include an inorganic material such as silicon oxide, silicon nitride, and the like. These may be used alone or in combination with each other.

The light blocking layer BL may be disposed on the protective layer PL. The light blocking layer BL may overlap (or disposed in) the non-light emitting area NEA. The light blocking layer BL may block light incident to the light blocking layer BL. Accordingly, the light blocking layer BL may prevent color mixing between the first light emitting area EA1, the second light emitting area EA2, and the third light emitting area EA3. An opening overlapping each of the first light emitting area EA1, the second light emitting area EA2, and the third light emitting area EA3 may be defined in the light blocking layer BL. For example, the light blocking layer BL may include an organic material or an inorganic material containing a black pigment or black dye.

The reflection control layer RCL may be disposed on the protective layer PL. The reflection control layer RCL may cover the light blocking layer BL. As the display device 100 includes the reflection control layer RCL, the display device 100 may not include a polarizer. For example, the reflection control layer RCL may replace the function of the polarizer. In other words, the reflection control layer RCL may selectively absorb external light reflected from the inside of the display device 100 according to a wavelength to prevent the light efficiency of the display device 100 from deteriorating.

The reflection control layer RCL may include an inorganic material and/or an organic material. For example, the reflection control layer RCL may include an organic material such as color photoresist. In an embodiment, the reflection control layer RCL may include negative color photoresist.

The reflection control layer RCL may further include at least one of solvent, dye, pigment, surfactant, and the like. For example, the reflection control layer RCL may include dye such as a tetraazaporphyrin-based compound, a porphyrin-based compound, an oxazine-based compound, a squarylium-based compound, a triarylmethane-based compound, a cyanine-based compound, an anthraquinone-based compound, an azo-based compound, a perylene-based compound, a xanthene-based compound, a dimonium-based compound, a dipyrromethene-based compound, and the like. These may be used alone or in combination with each other.

For example, the maximum absorption wavelength of the reflection control layer RCL may be in a wavelength range of about 530 nm to about 600 nm. For example, the reflection control layer RCL may absorb light having a wavelength outside of a wavelength range of red light, green light, or blue light emitted from the first, second, and third light emitting elements LED1, LED2, and LED3.

In an embodiment, a recess RS concavely depressed from an upper surface of the reflection control layer RCL may be defined on the reflection control layer RCL. The recess RS may overlap each of the first, second, and third light emitting areas EA1, EA2, and EA3.

The adhesive layer OL may be disposed on the reflection control layer RCL. The adhesive layer OL may continuously extend on the reflection control layer RCL. In an embodiment, the adhesive layer OL may directly contact the reflection control layer RCL. The adhesive layer OL may fill the recess RS of the reflection control layer RCL. The adhesive layer OL may include a transparent inorganic material and/or an organic material. For example, the adhesive layer OL may include at least one of optically clear adhesive (OCA), optically clear resin (OCR), pressure sensitive adhesive (PSA), and the like. These may be used alone or in combination with each other.

A cover window may be disposed on the adhesive layer OL. For example, the cover window may include glass and/or plastic. The cover window may be attached to the reflection control layer through the adhesive layer OL.

With respect to visible light, the reflection control layer RCL may have a relatively low refractive index, and the adhesive layer OL may have a relatively high refractive index. In an embodiment, with respect to visible light, the refractive index of the adhesive layer OL may be greater than the refractive index of the reflection control layer RCL. For example, the difference between the refractive index of the adhesive layer OL and the refractive index of the reflection control layer RCL may be about 0.05 or more. The difference between the refractive index of the adhesive layer OL and the refractive index of the reflection control layer RCL may be about 0.1 or more. In case that the difference between the refractive index of the adhesive layer OL and the refractive index of the reflection control layer RCL is less than 0.05, light efficiency of the display device 100 may decrease.

Due to the recess RS defined on the reflection control layer RCL and the difference in refractive index between the adhesive layer OL and the reflection control layer RCL, the recess RS of the reflection control layer RCL may perform a lens function. For example, among the lights emitted from the first, second, and third light emitting elements LED1, LED2, and LED3, lights L incident on the recess RS of the reflection control layer RCL may be emitted to the outside of the display device 100 in a direction perpendicular to the substrate SUB. Accordingly, light efficiency of the display device 100 may be improved.

As described above, the reflection control layer RCL may include an inorganic material and/or an organic material containing dye, pigment, solvent, surfactant, and the like. For example, the reflection control layer RCL may include at least one of a color photoresist containing dye, pigment, solvent, surfactant, and the like. Of the dye and pigment, the dye may be a main material of the reflection control layer RCL. A depth d of the recess RS of the reflection control layer RCL may be adjusted by adjusting a molecular weight of the color photoresist, a viscosity of the color photoresist, and an amount of the surfactant. For example, the function of the recess RS of the reflection control layer RCL as a lens may be improved by adjusting the molecular weight of the color photoresist, the viscosity of the color photoresist, and the amount of the surfactant. For example, in case that the molecular weight of the color photoresist is increased, the viscosity of the color photoresist is increased, or the amount of the surfactant is decreased, the depth d of the recess RS of the reflection control layer RCL may be increased.

According to a comparative example, in case that the upper surface of the reflection control layer RCL is entirely flat, light efficiency of the display device 100 including the reflection control layer RCL may decrease.

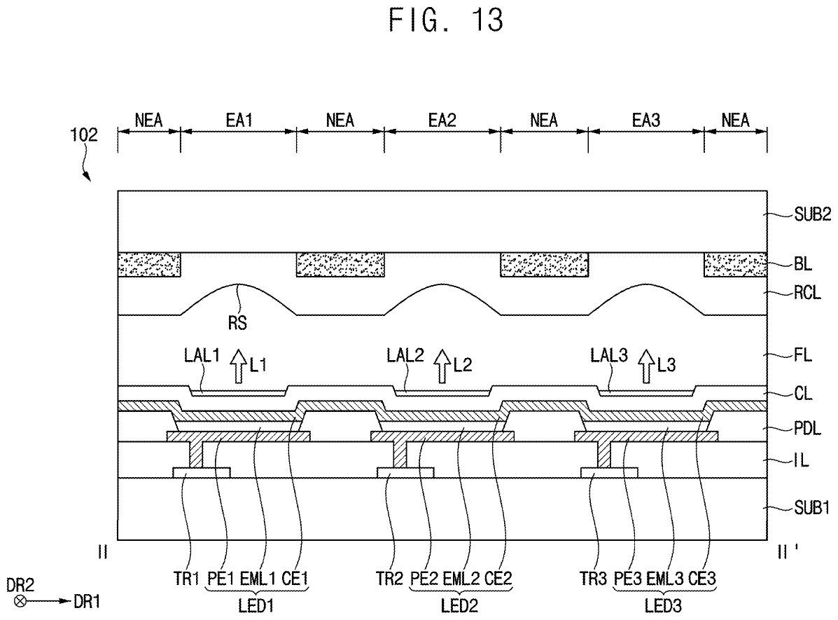

The display device 100 according to an embodiment of the disclosure may include the reflection control layer RCL on which the recesses RS concavely depressed from the upper surface are defined in first, second, and third light emitting areas EA1, EA2, and EA3 and a high refractive index layer (e.g., the adhesive layer OL of FIG. 2 or a filling layer FL of FIG. 13) which directly contacts the reflection control layer RCL. The refractive index of the high refractive index layer may be greater than the refractive index of the reflection control layer RCL. Accordingly, light efficiency of the display device 100 may be improved.

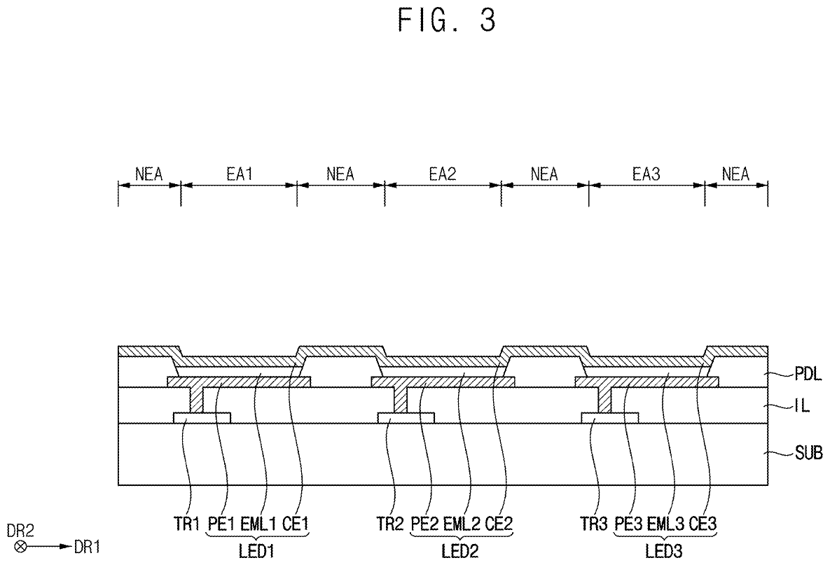

FIGS. 3, 4, 5, 6, 7, 8, and 9 are schematic cross-sectional views for explaining a method of manufacturing the display device of FIG. 2.

Referring to FIG. 3, the first, second, and third transistors TR1, TR2, and TR3, the insulating structure IL, the first, second, and third pixel electrodes PE1, PE2, and PE3, the pixel definition layer PDL, the first, second, and third light emitting layers EML1, EML2, and EML3, the first, second, and third common electrodes CE1, CE2, and CE3, and the capping layer CL may be sequentially formed on the substrate SUB.

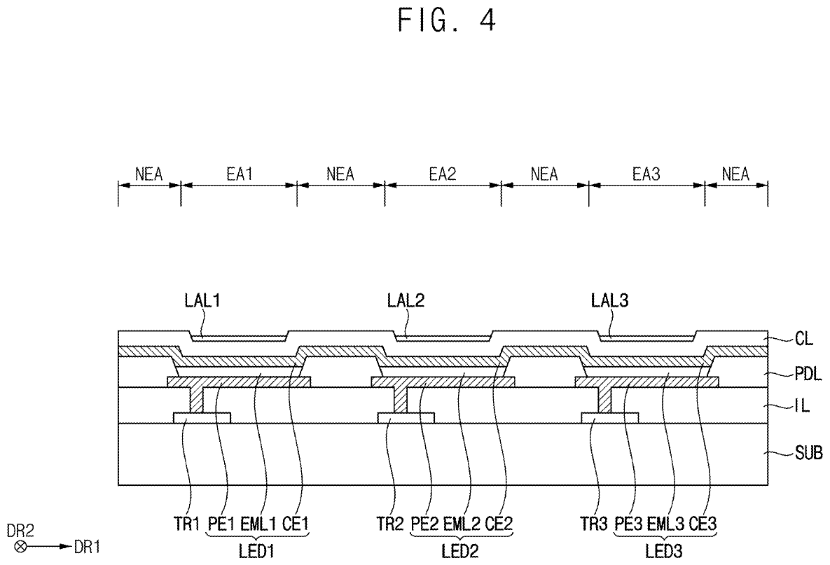

Referring to FIG. 4, the first, second, and third light absorbing layers LAL1, LAL2, and LAL3 may be formed on the capping layer CL. The first light absorbing layer LAL1 may be formed in the first light emitting area EA1, the second light absorbing layer LAL2 may be formed in the second light emitting area EA2, and the third light absorbing layer LAL3 may be formed in the third light emitting area EA3. For example, each of the first, second, and third light absorbing layers LAL1, LAL2, and LAL3 may be formed by using at least one of a metal, a silicon compound, a metal oxide, and the like.

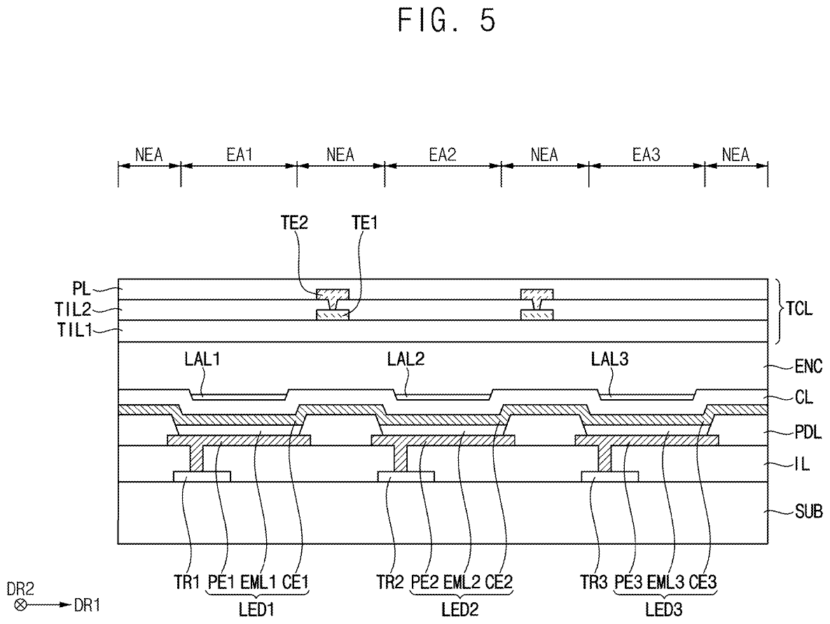

Referring to FIG. 5, the encapsulation layer ENC may be formed on the capping layer CL and the first, second, and third light absorbing layers LAL1, LAL2, and LAL3. The encapsulation layer ENC may include at least one of an inorganic encapsulation layer and an organic encapsulation layer.

The first touch insulating layer TIL1 may be formed on the encapsulation layer ENC. For example, the first touch insulating layer TIL1 may be formed by using an inorganic material. The first touch electrode TE1 may be formed on the first touch insulating layer TIL1. The second touch insulating layer TIL2 may be formed on the first touch insulating layer TIL1 and the first touch electrode TE1 For example, the second touch insulating layer TIL2 may be formed by using an inorganic material. The second touch electrode TE2 may be formed on the second touch insulating layer TIL2. The second touch electrode TE2 may be electrically connected to the first touch electrode TE1 through a contact hole formed by removing a portion of the second touch insulating layer TIL2. The protective layer PL may be formed on the second touch insulating layer TIL2 and the second touch electrode TE2. For example, the protective layer PL may be formed by using an inorganic material.

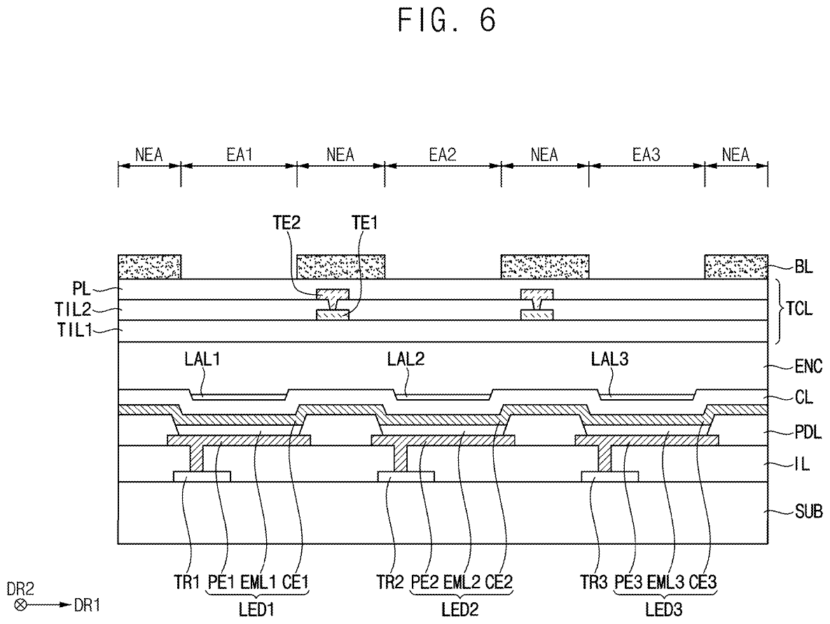

Referring to FIG. 6, the light blocking layer BL may be formed in the non-light emitting area NEA on the protective layer PL. For example, the light blocking layer BL may be formed by using an inorganic material and/or an organic material containing a light blocking material such as black pigment, black dye, and the like.

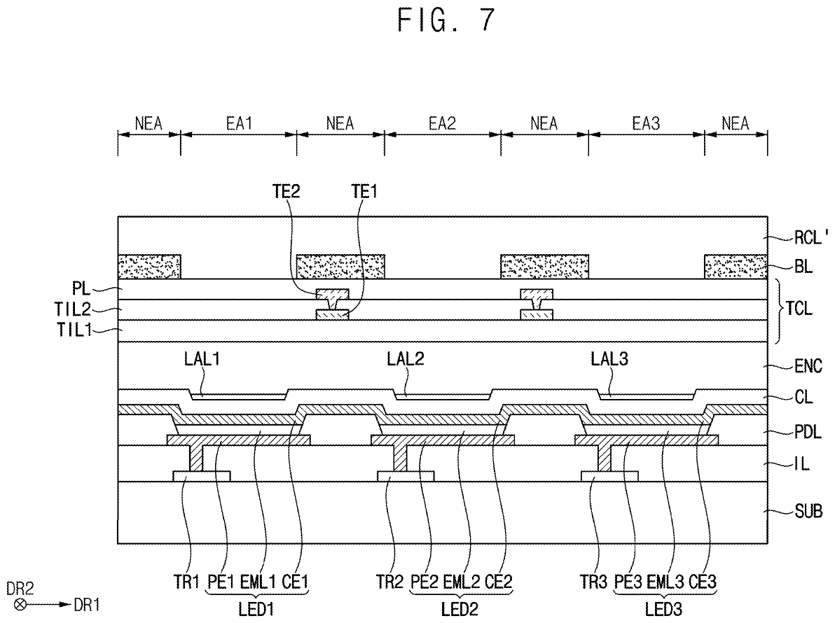

Referring to FIG. 7, a preliminary reflection control layer RCL′ may be formed on the protective layer PL. The preliminary reflection control layer RCL′ may cover the light blocking layer BL. For example, the preliminary reflection control layer RCL′ may be formed by using an inorganic material or an organic material containing dye, pigment, solvent, surfactant, and the like.

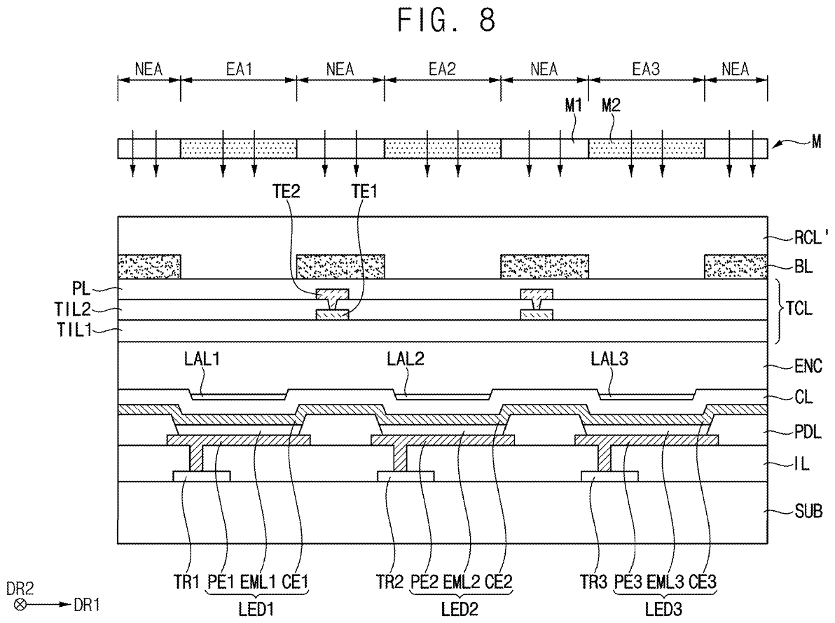

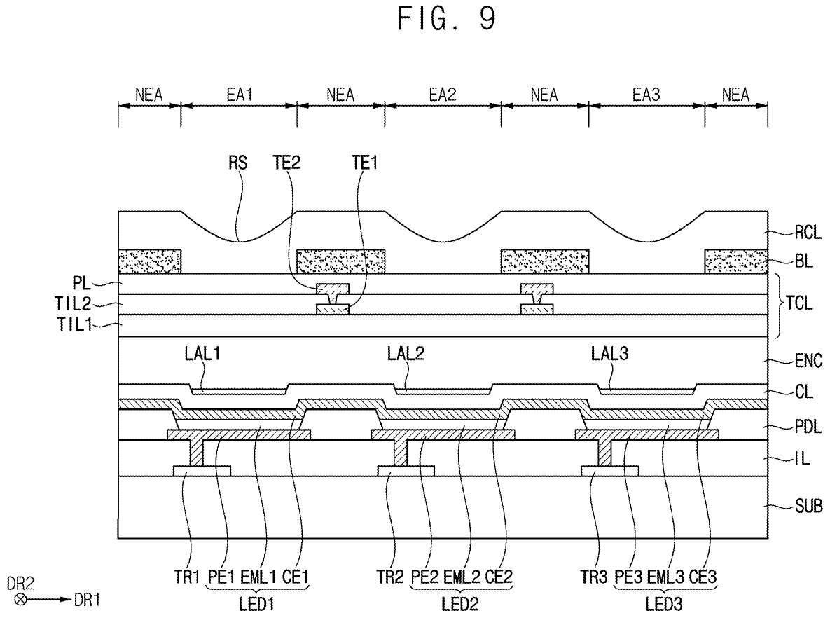

Referring to FIGS. 8 and 9, a mask M may be located on the preliminary reflection control layer RCL′. In an embodiment, the mask M may include a halftone mask and/or a slit mask. For example, the mask M may include a semi-transmission portion M2 and a light transmission portion M1. The light transmission portion M1 may transmit light, and the semi-transmission portion M2 may transmit only a portion of the light.

Exposure and development processes may be performed on the preliminary reflection control layer RCL′ through the mask M. A portion of the preliminary reflection control layer RCL′ corresponding to the light transmission portion M1 may not be removed. On the other hand, a portion of the preliminary reflection control layer RCL′ corresponding to the semi-transmission portion M2 may be partially removed. Accordingly, a reflection control layer RCL in which the recess RS concavely depressed from the upper surface is defined may be formed. The recess RS may overlap each of the first, second, and third light emitting areas EA1, EA2, and EA3.

In the exposure process performed on the preliminary reflection control layer RCL′, the thickness of the reflection control layer RCL may vary according to an exposure amount. For example, in the exposure process performed on the preliminary reflection control layer RCL′, the thickness of the reflection control layer RCL may increase as the amount of exposure increases.

Referring back to FIG. 2, the adhesive layer OL may be formed on the reflection control layer RCL. The adhesive layer OL may fill the recess RS of the reflection control layer RCL. For example, the adhesive layer OL may be formed by using an inorganic material and/or an organic material.

Accordingly, the display device 100 illustrated in FIG. 2 may be manufactured.

Hereinafter, the effect of the disclosure according to a comparative embodiment and embodiments 1 and 2 will be described with reference to FIG. 2.

In embodiment 1 and embodiment 2, the reflection control layer RCL in which the recesses RS concavely recessed from the upper surface are defined in the first, second, and third light emitting areas EA1, EA2, and EA3, was formed by using a color photoresist. The adhesive layer OL was formed on the reflection control layer RCL by using an acrylic resin.

In the comparative embodiment, a reflection control layer having a flat upper surface as a whole was formed by using a color photoresist. Then, an adhesive layer was formed on the reflection control layer by using an acrylic resin.

In embodiment 1, the refractive index of the reflection control layer RCL was about 1.48, and the refractive index of the adhesive layer OL was about 1.53. In embodiment 2, the refractive index of the reflection control layer RCL was about 1.48, and the refractive index of the adhesive layer OL was about 1.63.

Accordingly, light efficiency of the display device 100 satisfying embodiment 1, embodiment 2, and the comparative embodiment was measured.

TABLE 1

| | Difference of refractive index | Light efficiency (%) |
|---|---|---|
| Embodiment 1 | 0.05 | 102 |
| Embodiment 2 | 0.15 | 115 |
| Comparative | 0.03 | 100 |
| Embodiment | | |

As a result, referring to the Table 1, it may be confirmed that the light efficiency of the display device 100 satisfying embodiment 1 and embodiment 2 is higher than the light efficiency of the display device 100 satisfying the comparative example.

### Experimental Example 1: Comparison of Recess Depth According to Molecular Weight of Color Photoresist

### Preparation Example 1

As shown in Table 2 below, the reflection control layer RCL in which the recess RS concavely recessed from the upper surface is defined in the first, second, and third light emitting areas EA1, EA2, and EA3 was formed by using a color photoresist having a molecular weight of about 60,000 and containing dye, pigment, solvent, and surfactant. A thickness t of the reflection control layer RCL was about 3 Common materials were used for the dye and the pigment. Propylene glycol methyl ether acetate was used for the solvent, and F and Si-based surfactants were used.

### Preparation Example 2

As shown in Table 2 below, the reflection control layer RCL in which the recess RS concavely recessed from the upper surface is defined in the first, second, and third light emitting areas EA1, EA2, and EA3 was formed by using a color photoresist having a molecular weight of about 25,000 and containing dye, pigment, solvent, and surfactant. The thickness t of the reflection control layer RCL was 3 Common materials were used for the dye and the pigment. Propylene glycol methyl ether acetate was used for the solvent, and F and Si-based surfactants were used.

### Preparation Example 3

As shown in Table 2 below, the reflection control layer RCL in which the recess RS concavely recessed from the upper surface is defined in the first, second, and third light emitting areas EA1, EA2, and EA3 was formed by using a color photoresist having a molecular weight of 8,000 and containing dye, pigment, solvent, and surfactant. The thickness t of the reflection control layer RCL was about 3 Common materials were used for the dye and the pigment. Propylene glycol methyl ether acetate was used for the solvent, and F and Si-based surfactants were used.

### Preparation Example 4

As shown in Table 2 below, the reflection control layer RCL in which the recess RS concavely recessed from the upper surface is defined in the first, second, and third light emitting areas EA1, EA2, and EA3 was formed by using a color photoresist having a molecular weight of about 3,000 and containing dye, pigment, solvent, and surfactant. The thickness t of the reflection control layer RCL is about 3 Common materials were used for the dye and the pigment. Propylene glycol methyl ether acetate was used for the solvent, and F and Si-based surfactants were used.

TABLE 2

| | Molecular weight of | Thickness of reflection | Depth of recess |
|---|---|---|---|
| | color photoresist | control layer (μm) | (μm) |
| Preparation | 60,000 | 3 | 0.35 |
| Example 1 | | | |
| Preparation | 25,000 | 3 | 0.25 |
| Example 2 | | | |
| Preparation | 8,000 | 3 | 0.20 |
| Example 3 | | | |
| Preparation | 3,000 | 3 | 0.1 |
| Example 4 | | | |

As a result, referring to Table 2, it may be confirmed that the depth d of the recess RS of the reflection control layer RCL increases as the molecular weight of the color photoresist increases.

### Experimental Example 2: Comparison of Recess Depth According to Viscosity of Color Photoresist

### Preparation Example 5

As shown in Table 3 below, the reflection control layer RCL in which the recess RS concavely recessed from the upper surface is defined in the first, second, and third light emitting areas EA1, EA2, and EA3 was formed by using a color photoresist having a viscosity of 5 cp and containing dye, pigment, solvent, and surfactant. The thickness t of the reflection control layer RCL was about 2 Common materials were used for the dye and the pigment. Propylene glycol methyl ether acetate was used for the solvent, and F and Si-based surfactants were used.

### Preparation Example 6

As shown in Table 3 below, the reflection control layer RCL in which the recess RS concavely recessed from the upper surface is defined in the first, second, and third light emitting areas EA1, EA2, and EA3 was formed by using a color photoresist having a viscosity of about 16 cp and containing dye, pigment, solvent, and surfactant. The thickness t of the reflection control layer RCL was about 2 Common materials were used for the dye and the pigment. Propylene glycol methyl ether acetate was used for the solvent, and F and Si-based surfactants were used.

TABLE 3

| | Viscosity of color | Thickness of reflection | Depth of recess |
|---|---|---|---|
| | photoresist (cp) | control layer (μm) | (%) |
| Preparation | 5 | 2 | 100 |
| Example 5 | | | |
| Preparation | 16 | 2 | 110 |
| Example 6 | | | |

As a result, referring to Table 3, it may be confirmed that the depth d of the recess RS of the reflection control layer RCL increases as the viscosity of the color photoresist increases.

### Experimental Example 3: Comparison of the Thickness of the Reflection Control Layer According to the Amount of Exposure

### Preparation Example 7

As shown in Table 4 below, after forming a preliminary reflection control layer by using a color photoresist containing dye, pigment, solvent, and surfactant, the preliminary reflection control layer was exposed to light with an exposure amount of about 50 mJ and the preliminary reflection control layer was developed with potassium hydroxide (KOH) to form the reflection control layer RCL in which the recess RS concavely recessed from the upper surface is defined in the first, second, and third light emitting areas EA1, EA2, and EA3. Common materials were used for the dye and the pigment. Propylene glycol methyl ether acetate was used for the solvent, and F and Si-based surfactants were used.

### Preparation Example 8

As shown in Table 4 below, after forming a preliminary reflection control layer by using a color photoresist containing dye, pigment, solvent, and surfactant, the preliminary reflection control layer was exposed to light with an exposure amount of about 100 mJ and the preliminary reflection control layer was developed with potassium hydroxide (KOH) to form the reflection control layer RCL in which the recess RS concavely recessed from the upper surface is defined in the first, second, and third light emitting areas EA1, EA2, and EA3. Common materials were used for the dye and the pigment. Propylene glycol methyl ether acetate was used for the solvent, and F and Si-based surfactants were used. The color photoresist was used in the same amount as the color photoresist used in Preparation Example 7.

TABLE 4

| | Exposure amount | Thickness of reflection control |
|---|---|---|
| | (mJ) | layer (μm) |
| Preparation | 50 | 2.5 |
| Example 7 | | |
| Preparation | 100 | 3.0 |
| Example 8 | | |

As a result, referring to Table 4, it may be confirmed that the decrease rate of the thickness t of the reflection control layer RCL decreases as the exposure amount increases in the exposure process of forming the reflection control layer RCL.

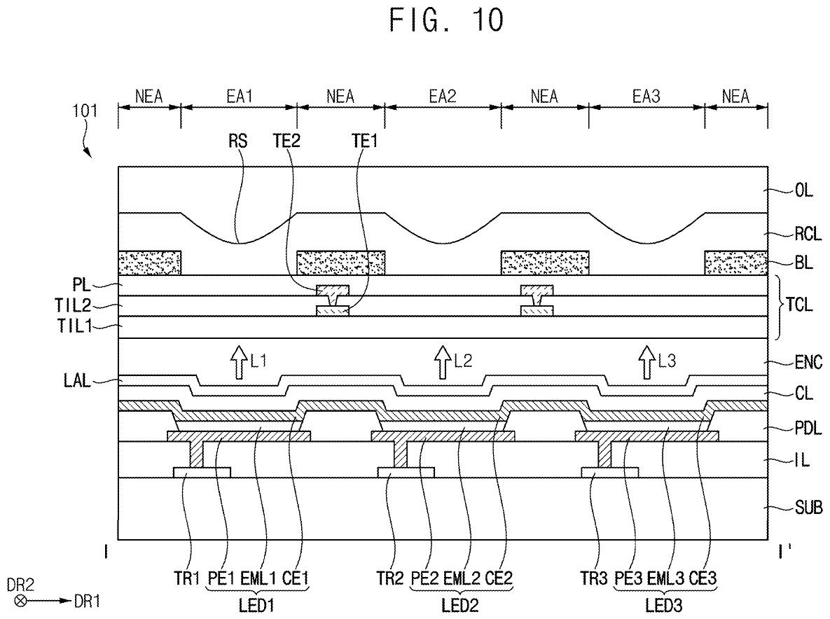

FIG. 10 is a schematic cross-sectional view illustrating a display device according to another embodiment of the disclosure.

Referring to FIG. 10, a display device 101 according to another embodiment of the disclosure may include a substrate SUB, first, second, and third transistors TR1, TR2, and TR3, an insulating structure IL, a pixel defining layer PDL, first, second, and third light emitting elements LED1, LED2, and LED3, a capping layer CL, light absorbing layer LAL, an encapsulation layer ENC, a touch sensing layer TCL, a light blocking layer BL, a reflection control layer RCL, and an adhesive layer OL. However, the display device 101 described with reference to FIG. 10 may be substantially the same as or similar to the display device 100 described with reference to FIG. 2 except for the shape of the light absorbing layer LAL. In the following, redundant descriptions are omitted or simplified.

The light absorbing layer LAL may be disposed on the capping layer CL. The light absorbing layer LAL may be entirely disposed in the first, second, and third light emitting areas EA1, EA2, and EA3 and the non-light emitting area NEA. For example, the light absorbing layer LAL may continuously extend on the capping layer CL. For example, the light absorbing layer LAL may include at least one of a metal, a silicon compound, a metal oxide, and the like. These may be used alone or in combination with each other.

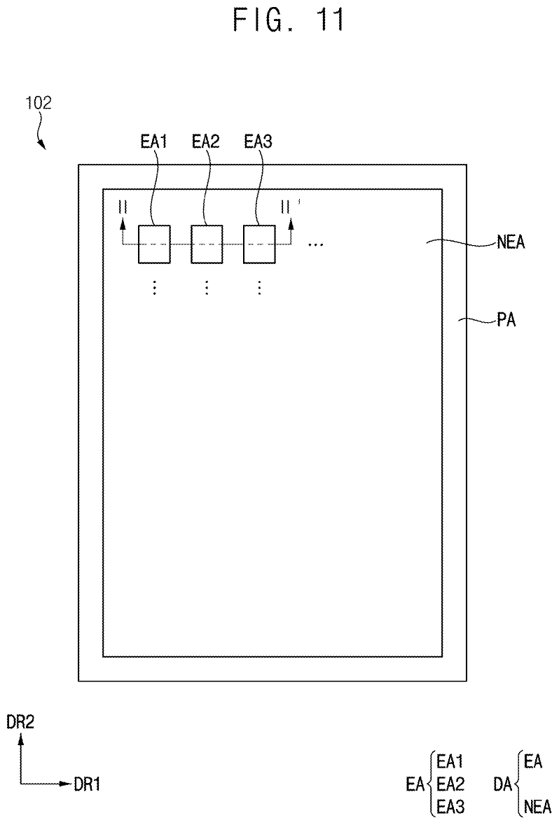

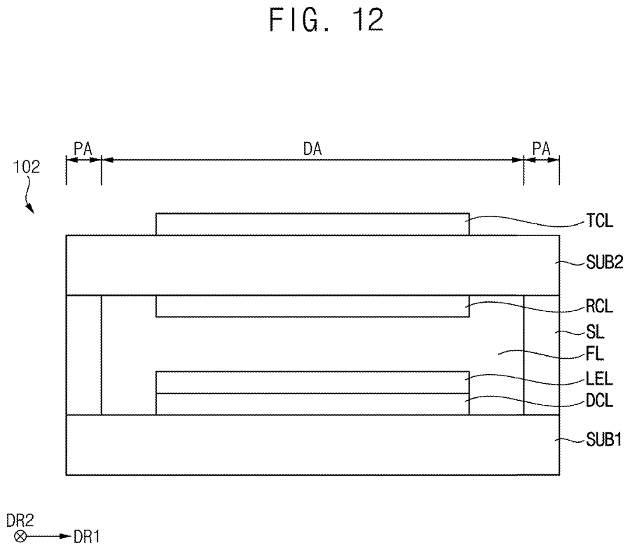

FIG. 11 is a schematic plan view illustrating a display device according to another embodiment of the disclosure. FIG. 12 is a cross-sectional view schematically illustrating the display device of FIG. 11.

Referring to FIGS. 11 and 12, a display device 102 according to another embodiment of the disclosure may include a display area DA and a peripheral area PA. The display area DA may include first, second, and third light emitting areas EA1, EA2, and EA3 and a non-light emitting area NEA. Hereinafter, repetitive descriptions with respect to those of the display device 100 described with reference to FIG. 1 will be omitted or simplified.

The display device 102 may include a first substrate SUB1, a circuit layer DCL, a light emitting element layer LEL, a filling layer FL, a sealing member SL, a reflection control layer RCL, a second substrate SUB2, and a touch sensing layer TCL.

The first substrate SUB1 may include a transparent material and/or an opaque material. For example, the first substrate SUB1 may include glass, plastic, or the like.

The circuit layer DCL may be disposed on the first substrate SUB1. The circuit layer DCL may overlap the display area DA. For example, the circuit layer DCL may include a transistor, an insulating structure, and the like. The light emitting element layer LEL may be disposed on the circuit layer DCL. The light emitting element layer LEL may be electrically connected to the circuit layer DCL. For example, the light emitting element layer LEL may include a light emitting element that emits light of a color (e.g., a predetermined or selectable color).

The sealing member SL may be disposed in the peripheral area PA of the first substrate SUB1. The sealing member SL may be disposed to surround the display area DA in a plan view, and the first substrate SUB1 and the second substrate SUB2 may be bonded through the sealing member SL. The sealing member SL may prevent foreign substances, moisture, and the like from penetrating into the display device 102 from the outside.

The second substrate SUB2 may be disposed to face the first substrate SUB1. In an embodiment, the second substrate SUB2 may be an encapsulation substrate. The second substrate SUB2 and the first substrate SUB1 may include a same material. For example, the second substrate SUB2 may include glass, plastic, or the like.

The reflection control layer RCL may be disposed under the second substrate SUB2. The reflection control layer RCL may reduce reflectance due to external light. A detailed description of the reflection control layer RCL will be described below.

The touch sensing layer TCL may be disposed on the second substrate SUB2. The touch sensing layer TCL may include touch electrodes and may sense a user's touch.

The filling layer FL may be disposed between the first substrate SUB1 and the second substrate SUB2. A filler may be filled in the filling layer FL. For example, the filler may include air, an organic polymer material, a resin, and the like. The filling layer FL may improve high-temperature stability and shock absorption of the display device 102.

FIG. 13 is a schematic cross-sectional view taken along line II-II′ of FIG. 11.

Referring to FIG. 13, the display device 102 according to another embodiment of the disclosure may include the first substrate SUB1, first, second, and third transistors TR1, TR2, and TR3, an insulating structure IL, first, second, and third light emitting elements LED1, LED2, and LED3, a pixel defining layer PDL, a capping layer CL, first, second, and third light absorbing layers LAL1, LAL2, and LAL3, the filling layer FL, the reflection control layer RCL, a light blocking layer BL, and the second substrate SUB2. Hereinafter, repetitive descriptions with respect to those of the display device 100 described with reference to FIG. 2 will be omitted or simplified.

The first, second, and third transistors TR1, TR2, and TR3, the insulating structure IL, the first, second, and third light emitting elements LED1, LED2, and LED3, the pixel defining layer PDL, the capping layer CL, and the first, second, and third light absorbing layers LAL1, LAL2, and LAL3 may be sequentially disposed on the first substrate SUB1.

The second substrate SUB2 may be disposed to face the first substrate SUB1. A light blocking layer BL may be disposed under the second substrate SUB2. The light blocking layer BL may overlap the non-light emitting area NEA. For example, the light blocking layer BL may include an inorganic material and/or an organic material containing a light blocking material such as black pigment, black dye, and the like.

The reflection control layer RCL may be disposed under the second substrate SUB2. For example, the reflection control layer RCL may include an inorganic material and/or an organic material containing pigment, dye, solvent, surfactant, and the like. In an embodiment, a recess RS concavely depressed from an upper surface of the reflection control layer RCL may be defined on the reflection control layer RCL. The recess RS may overlap each of the first, second, and third light emitting areas EA1, EA2, and EA3.

The filling layer FL may be disposed on the first substrate SUB1 and the second substrate SUB2. The filling layer FL may be disposed between the capping layer CL and the reflection control layer RCL. In an embodiment, the filling layer FL may directly contact the reflective control layer RCL. For example, the filling layer FL may fill the recess RS of the reflection control layer RCL.

In an embodiment, with respect to visible light, the refractive index of the filling layer FL may be greater than the refractive index of the reflection control layer RCL. For example, the difference between the refractive index of the filling layer FL and the refractive index of the reflection control layer RCL may be about 0.05 or more. The difference between the refractive index of the filling layer FL and the refractive index of the reflection control layer RCL may be about 0.1 or more.

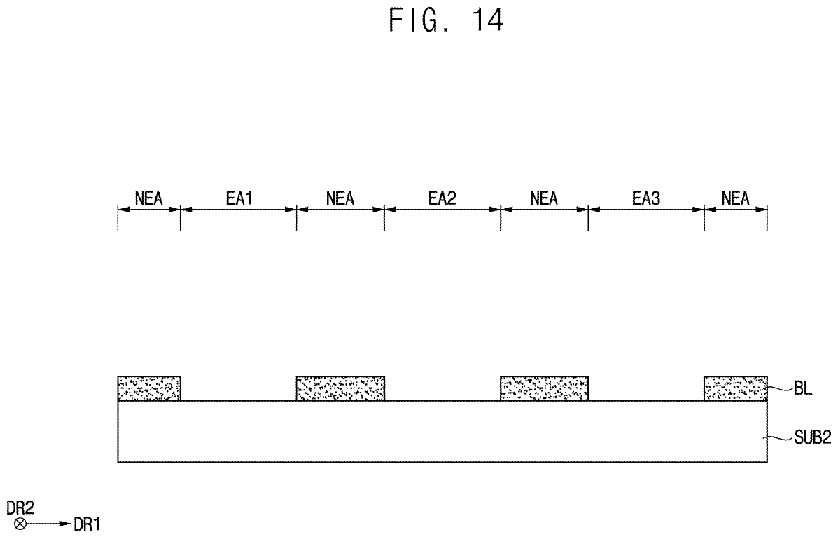

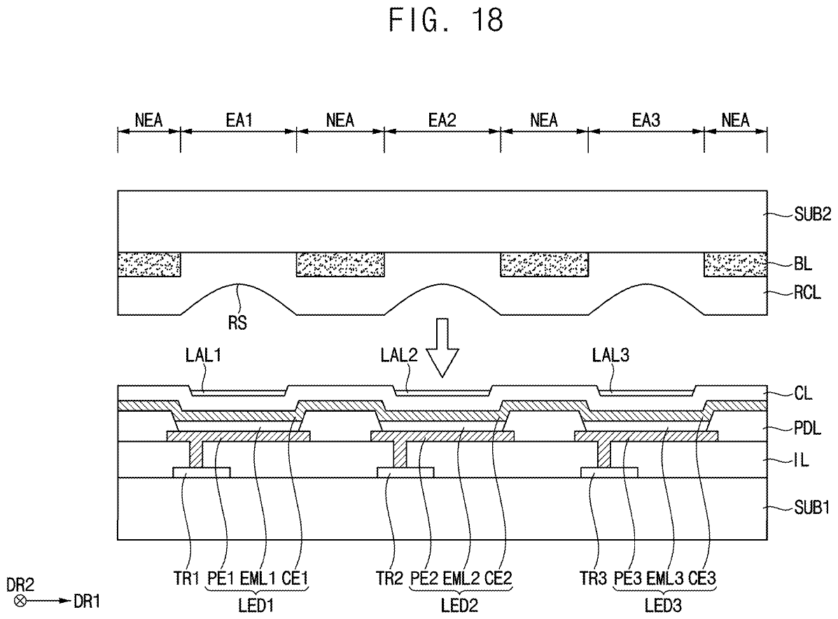

FIGS. 14, 15, 16, 17, and 18 are schematic cross-sectional views for explaining a method of manufacturing the display device of FIG. 13.

Hereinafter, repetitive descriptions with respect to the method of manufacturing the display device 100 described with reference to FIGS. 3, 4, 5, 6, 7, 8, and 9 will be omitted or simplified.

Referring to FIG. 14, the light blocking layer BL may be formed on the second substrate SUB2. The light blocking layer BL may overlap the non-light emitting area NEA. For example, the light blocking layer BL may be formed by using an inorganic material and/or an organic material containing a light blocking material.

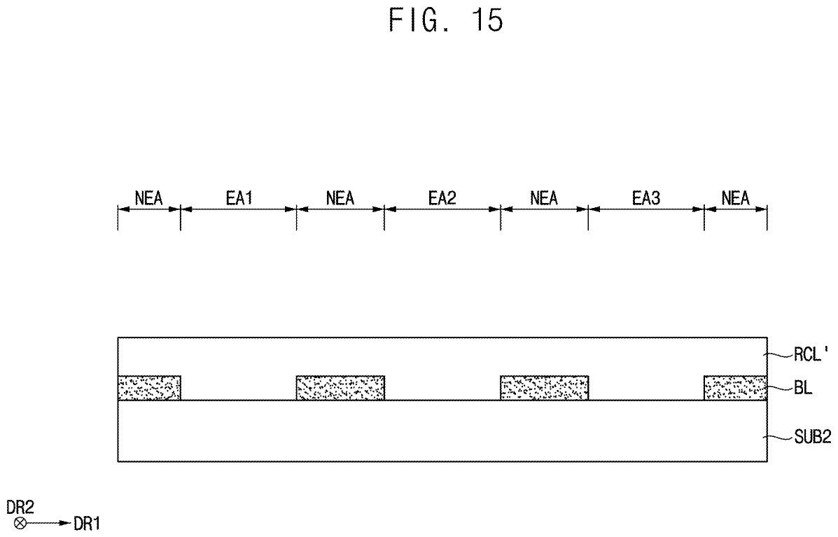

Referring to FIG. 15, a preliminary reflection control layer RCL′ may be formed on the second substrate SUB2. The preliminary reflection control layer RCL′ may cover the light blocking layer BL. For example, the preliminary reflection control layer RCL′ may be formed by using an inorganic material or an organic material containing dye, pigment, solvent, surfactant, and the like.

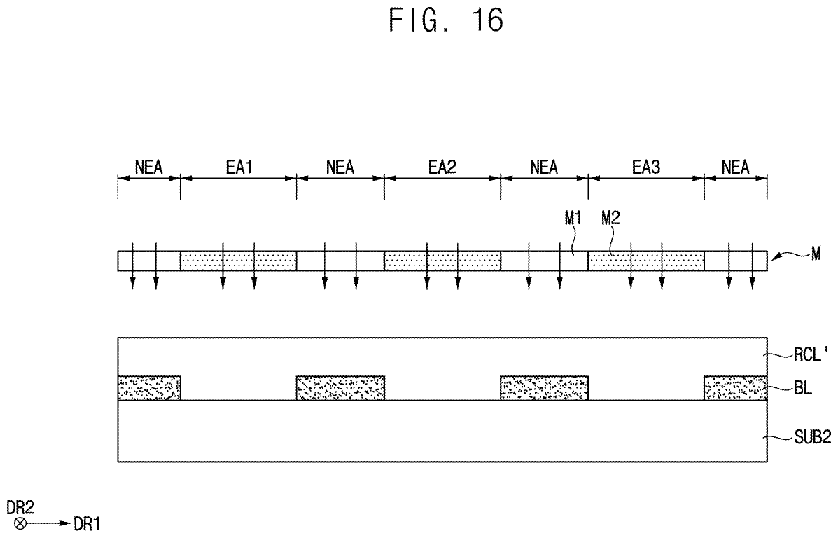

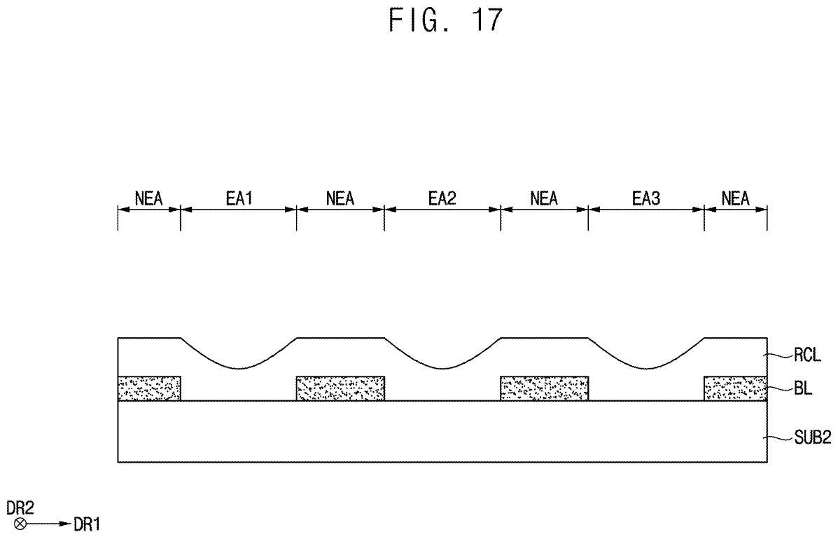

Referring to FIGS. 16 and 17, a mask M may be located on the preliminary reflection control layer RCL′. For example, the mask M may include a semi-transmission portion M2 and a light transmission portion M1. The light transmission portion M1 may transmit all light, and the semi-transmission portion M2 may transmit only a portion of the light.

Exposure and development processes may be performed on the preliminary reflection control layer RCL′ through the mask M. A portion of the preliminary reflection control layer RCL′ corresponding to the light transmission portion M1 may not be removed. On the other hand, a portion of the preliminary reflection control layer RCL′ corresponding to the semi-transmission portion M2 may be partially removed. Accordingly, the reflection control layer RCL in which the recess RS concavely depressed from the upper surface is defined may be formed. The recess RS may overlap each of the first, second, and third light emitting areas EA1, EA2, and EA3.

Referring to FIGS. 2, 13, and 18, the first, second, and third transistors TR1, TR2, and TR3, the insulating structure IL, the first, second, and third light emitting elements LED1, LED2, and LED3, the pixel defining layer PDL, the capping layer CL, and the first, second, and third light absorbing layers LAL1, LAL2, and LAL3 may be sequentially formed on the first substrate SUB1.

The first substrate SUB1 and the second substrate SUB2 may be bonded through the sealing member SL. A filler may be filled between the capping layer CL and the reflection control layer RCL. For example, the filler may be (or may include) at least one of air, an organic polymer material, a resin, and the like. As the first substrate SUB1 and the second substrate SUB2 are bonded together, the filling layer FL including the filler may be defined.

Accordingly, the display device 102 illustrated in FIG. 13 may be manufactured.

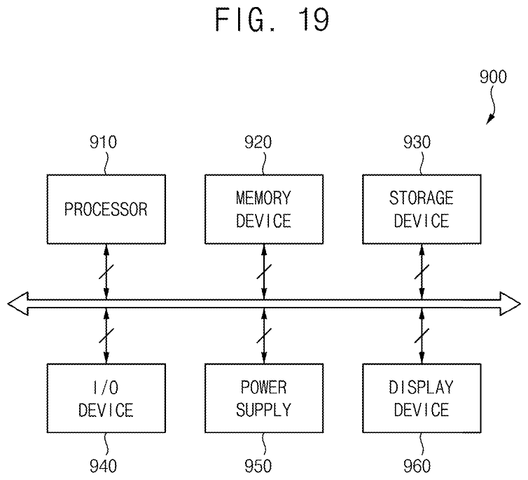

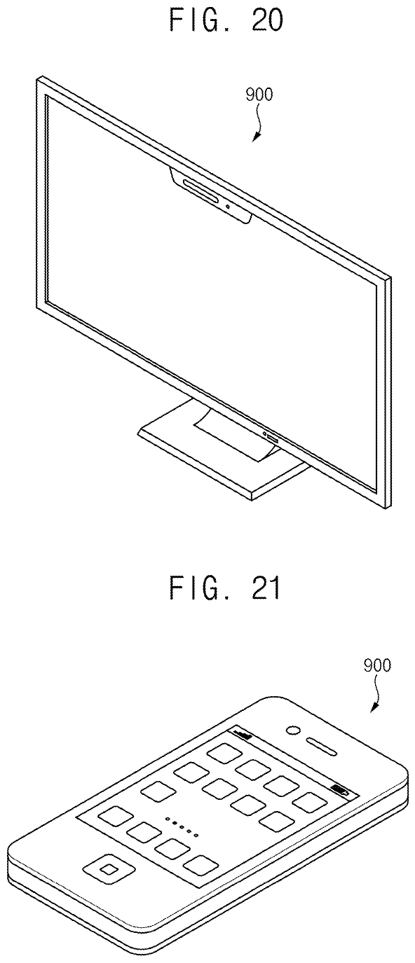

FIG. 19 is a schematic block diagram illustrating an electronic device including the display device of FIG. 1. FIG. 20 is a schematic diagram illustrating an example in which the electronic device of FIG. 19 is implemented as a television. FIG. 21 is a schematic diagram illustrating an example in which the electronic device of FIG. 19 is implemented as a smartphone.

Referring to FIGS. 19, 20, and 21, in an embodiment, an electronic device 900 may include at least one of a processor 910, a memory device 920, a storage device 930, an input/output (I/O) device 940, a power supply 950 and a display device 960. The display device 960 may correspond to the display device 100, 101, and 102 described with reference to FIGS. 1 to 18. The electronic device 900 may further include various ports capable of communicating with a video card, a sound card, a memory card, a USB device, and the like.

In an embodiment, as illustrated in FIG. 20, the electronic device 900 may be implemented as a television. In another embodiment, as illustrated in FIG. 21, the electronic device 900 may be implemented as a smartphone. However, the electronic device 900 is not limited thereto, and in another embodiment, the electronic device 900 may be implemented as a cellular phone, a video phone, a smart pad, a smart watch, a tablet personal computer (PC), a car navigation system, a computer monitor, a laptop, a head-mounted display (HMD), or the like.

The processor 910 may perform various computing functions. In an embodiment, the processor 910 may be at least one a microprocessor, a central processing unit (CPU), an application processor (AP), or the like. The processor 910 may be coupled to other components via an address bus, a control bus, a data bus, or the like. The processor 910 may be coupled to an extended bus such as a peripheral component interconnect (PCI) bus. The processor 910 may be at least one processor, with any one of the at least one processor, separately or in combination, being configured to perform one or more operations.

The memory device 920 may store data for operations of the electronic device 900. In an embodiment, the memory device 920 may include at least one of a non-volatile memory device and a volatile memory device. The non-volatile memory device may be, for example, an erasable programmable read-only memory (EPROM) device, an electrically erasable programmable read-only memory (EEPROM) device, a flash memory device, a phase change random access memory (PRAM) device, a resistive random access memory (RRAM) device, a nano floating gate memory (NFGM) device, a polymer random access memory (PoRAM) device, a magnetoresistive random access memory (MRAM) device, a ferroelectric random access memory (FRAM) device, or the like. The volatile memory device may be a dynamic random access memory (DRAM) device, a static random access memory (SRAM) device, a mobile DRAM device, or the like.

The storage device 930 may include at least one of a solid-state drive (SSD) device, a hard disk drive (HDD) device, a compact disc read-only memory (CD-ROM) device, and the like.

The I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The display device 960 may be coupled or connected to other components via the buses or other communication links. In an embodiment, the display device 960 may be included in the I/O device 940.

The disclosure can be applied to various display devices. For example, the disclosure is applicable to various display devices such as display devices for vehicles, ships and aircraft, portable communication devices, display devices for exhibition or information transmission, medical display devices, and the like.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a light emitting area and a non-light emitting area;
a light emitting element disposed in the light emitting area on a substrate and including:
a pixel electrode;
a light emitting layer; and
an upper electrode, the pixel electrode, light emitting layer, and upper electrode being sequentially disposed;
a light blocking layer disposed on the light emitting element in the non-light emitting area; and
a reflection control layer disposed on the light emitting element, covering the light blocking layer, and including a recess concavely depressed from an upper surface in the light emitting area.

2. The display device of claim 1, further comprising:
an adhesive layer disposed on the reflection control layer,
wherein a refractive index of the adhesive layer is greater than a refractive index of the reflection control layer.

3. The display device of claim 2, wherein a difference between the refractive index of the adhesive layer and the refractive index of the reflection control layer is about 0.05 or more.

4. The display device of claim 2, wherein the adhesive layer directly contacts the reflection control layer.

5. The display device of claim 1, further comprising:
a filling layer disposed between the light emitting element and the reflection control layer,
wherein a refractive index of the filling layer is greater than a refractive index of the reflection control layer.

6. The display device of claim 5, wherein the filling layer directly contacts the reflection control layer.

7. The display device of claim 5, wherein a difference between the refractive index of the filling layer and the refractive index of the reflection control layer is about 0.05 or more.

8. The display device of claim 1, further comprising:
a light absorbing layer disposed on the upper electrode and including an inorganic material.

9. The display device of claim 8, wherein the light absorbing layer is disposed only in the light emitting area.

10. The display device of claim 8, wherein the light absorbing layer is entirely disposed in the light emitting area and the non-light emitting area.

11. The display device of claim 8, wherein the light absorbing layer includes at least one selected from a group consisting of a metal, a silicon compound, and a metal oxide.

12. The display device of claim 1, wherein the reflection control layer includes an inorganic material or an organic material.

13. The display device of claim 12, wherein the reflection control layer further includes at least one selected from a group consisting of solvent, dye, pigment, and surfactant.

14. The display device of claim 12, wherein the organic material includes photoresist.

15. The display device of claim 1, further comprising:
a touch sensing layer disposed between the light emitting element and the light blocking layer, and including a first touch electrode and a second touch electrode electrically connected to the first touch electrode.

16. A method of manufacturing a display device, the method comprising:
forming a light emitting element including a pixel electrode, a light emitting layer, and an upper electrode sequentially formed in a light emitting area of the display device on a substrate;
forming a light blocking layer in a non-light emitting area of the display device on the light emitting element;
forming a preliminary reflection control layer covering the light blocking layer on the light emitting element; and
forming a reflection control layer including a recess concavely depressed from an upper surface in the light emitting area by removing a portion of the preliminary reflection control layer in the light emitting area.

17. The method of claim 16, wherein the forming the reflection control layer is performed by using a halftone mask or a slit mask.

18. The method of claim 16, further comprising:
forming an adhesive layer on the reflection control layer,
wherein a refractive index of the adhesive layer is greater than a refractive index of the reflection control layer.

19. The method of claim 18, wherein a difference between the refractive index of the adhesive layer and the refractive index of the reflection control layer is about 0.05 or more.

20. The method of claim 18, wherein the adhesive layer directly contacts the reflection control layer.

21. The method of claim 16, further comprising:
forming a light absorbing layer including an inorganic material on the upper electrode after the forming of the light emitting element.

22. The method of claim 16, wherein the reflection control layer includes an inorganic material or an organic material.

23. The method of claim 22, wherein the reflection control layer further includes at least one selected from a group consisting of solvent, dye, pigment, and surfactant.
